(19) United States
(12) Patent Application Publication
(10) Pub. No.: US 2003/0194496 A1
(43) Pub. Date: Oct. 16, 2003

(54) Methods for depositing dielectric material

(75) Inventors: Ping Xu, Fremont, CA (US); Li-Qun Xia, Santa Clara, CA (US); Huong Thanh Nguyen, San Ramon, CA (US); Louis Yang, San Francisco, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/122,106

(22) Filed: Apr. 11, 2002

(51) Int. Cl. C23C 16/00; B05D 3/02

(52) U.S. Cl. 427/255.28; 427/569; 427/372.2

(57) ABSTRACT

Methods are provided for depositing a low dielectric constant material. In one aspects, a method is provided for depositing a low dielectric constant material including introducing a processing gas comprising hydrogen and an oxygen-containing organosilicon compound, an oxygen-free organosilicon compound, or combinations thereof, to a substrate surface in a processing chamber and reacting the processing gas at processing conditions to deposit the low dielectric constant material on the substrate surface, wherein the low k dielectric material comprises at least silicon and carbon. The processing gas may further include an inert gas, a meta-stable compound, or combinations thereof. The method may further include treating the low dielectric constant material with a hydrogen containing plasma, annealing the deposited low dielectric constant material, or combinations thereof.

### BACKGROUND OF THE DISCLOSURE

1. Field of the Invention

The invention relates to the fabrication of integrated circuits and to a process for depositing dielectric layers on a substrate.

2. Description of the Related Art

One of the primary steps in the fabrication of modern semiconductor devices is the formation of metal and dielectric layers on a substrate by chemical reaction of gases. Such deposition processes are referred to as chemical vapor deposition or CVD. Conventional thermal CVD processes supply reactive gases to the substrate surface where heat-induced chemical reactions take place to produce a desired layer. Plasma enhanced CVD (PECVD) processes typically use radio frequency (RF) or microwave power to promote chemical reactions to produce a desired layer.

Semiconductor device geometries have dramatically decreased in size since such devices were first introduced several decades ago. Since then, integrated circuits have generally followed the “two year/half-size” rule (often called Moore's Law), which means that the number of devices that will fit on a chip doubles every two years. Today's fabrication plants are routinely producing devices having 0.35 μm and even 0.18 μm feature sizes, and tomorrow's plants soon will be producing devices having even smaller geometries.

To further reduce the size of devices on integrated circuits, it has become necessary to use conductive materials having low resistivity and to use insulators having low dielectric constants (dielectric constant<5.0) to also reduce the capacitive coupling between adjacent metal lines. Such low k materials include spin-on glass, such as un-doped silicon glass (USG) or fluorine-doped silicon glass (FSG), which can be deposited as a gap fill layer in a semiconductor manufacturing process, and silicon oxycarbide which can used as a dielectric layer in fabricating damascene features.

However, deposited low k films may contain contaminants in porous structures that result in greater than desired dielectric constant, less than desirable layer stability, and less than desirable mechanical properties. Additionally, low k materials are susceptible to surface defects, contamination, or feature deformation during subsequent deposition and removal of conductive materials under conventional processes.

Therefore, there remains a need for an improved process for depositing low k dielectric materials with reduced or low dielectric constants and improved layer properties.

### SUMMARY OF THE INVENTION

Aspects of the invention generally provide methods for depositing low dielectric constant materials. In one aspect, a method is provided for depositing a low dielectric constant material including introducing a processing gas comprising hydrogen gas and an oxygen-containing organosilicon compound, an oxygen-free organosilicon compound, or combinations thereof, to a substrate surface in a processing chamber and reacting the processing gas at processing conditions to deposit a low dielectric constant material on the substrate surface, wherein the low k dielectric material comprises at least silicon and carbon. The processing gas may further include an inert gas, a meta-stable compound, or combinations thereof. The method may further include treating the low dielectric constant material with a hydrogen containing plasma, annealing the deposited low dielectric constant material, or combinations thereof.

In another aspect, a method is provided for processing a substrate including reacting a processing gas comprising one or more cyclic organosilicon compounds, one or more aliphatic compounds, and hydrogen gas, and delivering the processing gas to a substrate surface at conditions sufficient to deposit a low dielectric constant layer on a substrate surface. The processing gas may further include an inert gas, a meta-stable compound, or combinations thereof. The method may further include treating the deposited low dielectric constant material with a hydrogen containing plasma.

### DETAILED DESCRIPTION OF THE PREFERRED EMBODIMENTS

Aspects of the invention described herein refer to methods for depositing low k dielectric films. Low k dielectric materials deposited by the methods described herein have lower dielectric constants, improved layer stability, and improved mechanical properties compared to materials deposited by prior processes. Low k dielectric materials deposited by the methods described herein generally have dielectric constants between about 2.5 and about 4.5.

Silicon Carbide Materials

In one aspect, low dielectric constant (low K) materials may be deposited by reacting a processing gas including hydrogen gas and an oxygen-free organosilicon compound to form a dielectric layer comprising carbon-silicon bonds having a dielectric constant less than about 5. The low k dielectric material may be deposited by a thermal or plasma-enhanced chemical vapor deposition process. The deposited low dielectric constant material may be treated with a hydrogen containing plasma, an annealing process, or both. The silicon carbide material may be used as an interlayer dielectric material, an etch stop, a barrier layer adjacent a conductive material, a chemical mechanical polishing resistant layer (CMP stop), a hardmask layer, or an anti-reflective coating (ARC).

Organosilicon compounds contain carbon atoms in organic groups and at least one of the carbon atoms bonded to a silicon atom. Low dielectric constant layers are prepared from organosilicon compounds that have one or more carbon atoms attached to silicon wherein the carbon is not readily removed by oxidation at suitable processing conditions. The organosilicon compounds used preferably include the structure:

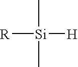

wherein R includes alkyl, alkenyl, cyclohexenyl, and aryl groups in addition to functional derivatives thereof. However, the invention contemplates the use of organosilicon precursors without Si—H bonds.

Suitable oxygen-free organosilicon compounds include oxygen-free aliphatic organosilicon compounds, oxygen-free cyclic organosilicon compounds, or combinations thereof, having at least one silicon-carbon bond. Cyclic organosilicon compounds typically have a ring comprising three or more silicon atoms. Aliphatic organosilicon compounds have linear or branched structures comprising one or more silicon atoms and one or more carbon atoms. Commercially available aliphatic organosilicon compounds include alkylsilanes.

Examples of suitable oxygen-free organosilicon compounds include one or more of the following compounds:

| | |
|---|---|
| Methylsilane, | CH₃—SiH₃ |
| Dimethylsilane, | (CH₃)₂—SiH₂ |
| Trimethylsilane (TMS), | (CH₃)₃—SiH |
| Ethylsilane, | CH₃—CH₂—SiH₃ |
| Disilanomethane, | SiH₃—CH₂—SiH₃ |
| Bis(methylsilano)methane, | CH₃—SiH₂—CH₂—SiH₂—CH₃ |
| 1,2-disilanoethane, | SiH₃—CH₂—CH₂—SiH₃ |
| 1,2-bis(methylsilano)ethane, | CH₃—SiH₂—CH₂—CH₂—SiH₂—CH₃ |
| 2,2-disilanopropane, | SiH₃—C(CH₃)₂—SiH₃ |
| 1,3,5-trisilano-2,4,6- | ( SiH₂CH₂)₃ (cyclic) |
| trimethylene, | |
| Diethylsilane | (C₂H₅)₂SiH₂) |
| Propylsilane | C₃H₇SiH₃ |
| Vinylmethylsilane | (CH₂═CH)(CH₃)SiH₂ |
| 1,1,2,2-tetramethyldisilane | HSi(CH₃)₂—Si(CH₃)₂H |
| Hexamethyldisilane | (CH₃)₃Si—Si(CH₃)₃ |
| 1,1,2,2,3,3-hexamethyltrisilane | H(CH₃)₂Si—Si(CH₃)₂—SiH(CH₃)₂ |
| 1,1,2,3,3-pentamethyltrisilane | H(CH₃)₂Si—SiH(CH₃)—SiH(CH₃)₂ |
| Dimethyldisilanoethane | CH₃—SiH₂—(CH₂)₂—SiH₂—CH₃ |
| Dimethyldisilanopropane | CH₃—SiH₂—(CH₂)₃—SiH₂—CH₃ |
| Tetramethyldisilanoethane | (CH)₂—SiH—(CH₂)₂—SiH—(CH)₂ |
| Tetramethyldisilanopropafle | (CH₃)₂—SiH—(CH₂)₃—SiH—(CH₃)₂ |

and fluorinated hydrocarbon derivatives thereof.

The processing gas may also include hydrogen gas. The hydrogen gas is generally added at a molar ratio of oxygen-free organosilicon compound to hydrogen gas of between about 1:1 and about 10:1, such as between about 1:1 and about 6:1. Preferred deposition processes for oxygen-free organosilicon compounds and hydrogen gas has a molar ratio of oxygen-free organosilicon compound to hydrogen gas of between about 1:1 and about 1.5:1.

Inert gases, such as a noble gas selected from the group of argon, helium, neon, xenon, or krypton, and combinations thereof, may be added to the processing gas to improve processing stability.

The low k dielectric material deposition processes described herein may be performed in a processing chamber adapted to chemically mechanically deposit organosilicon material while applying RF power, such as a DxZ™ chemical vapor deposition chamber or the Producer™ chemical vapor deposition chamber, commercially available from Applied Materials, Inc., Santa Clara, Calif. Generally, the organosilicon compound and hydrogen gas are reacted in a plasma comprising a noble gas, such as helium, argon or a relatively inert gas, such as nitrogen (N₂). The deposited silicon carbide layers have dielectric constants of about 5 or less, preferably about 4 or less.

A silicon carbide layer may be deposited in one embodiment by supplying an oxygen-free organosilicon compound, such as trimethylsilane, to a plasma processing chamber at a flow rate between about 10 milligrams/minute (mgm) and about 1500 mgm, respectively, supplying hydrogen gas at a flow rate between about 10 sccm and about 2000 sccm, supplying a noble gas at a flow rate between about 1 sccm and about 10000 sccm, maintaining a substrate temperature between about 0° C. and about 500° C., maintaining a chamber pressure below about 500 Torr, and supplying an RF power of between about 0.03 watts/cm² and about 1500 watts/cm².

The RF power can be provided at a high frequency such as between 13 MHz and 14 MHz or a mixed frequency of the high frequency and the low frequency, for example, a high frequency of about 13.56 MHz and a low frequency of between about 100 KHz and about 1000 KHz, such as about 356 KHz. The RF power can be provided continuously or in short duration cycles wherein the power is on at the stated levels for cycles less than about 200 Hz and the on cycles total between about 10% and about 30% of the total duty cycle. The processing gas may be introduced into the chamber by a gas distributor, the gas distributor may be positioned between about 200 mils and about 700 mils from the substrate surface.

In one preferred aspect, a low dielectric constant silicon carbide layer may be deposited in one embodiment by supplying an oxygen-free organosilicon compound, such as trimethylsilane, to a plasma processing chamber at a flow rate between about 100 milligrams/minute (mgm) and about 5000 mgm, supplying hydrogen gas at a flow rate between about 10 sccm and about 200 sccm at a molar ratio of oxygen-free organosilicon compound, i.e., trimethylsilane, to hydrogen gas between about 6:1 and about 1:1, supplying a noble gas at a flow rate between about 500 sccm and about 2000 sccm, maintaining a substrate temperature between about 250° C. and about 450° C., maintaining a chamber pressure between about 1 Torr and about 12 Torr and supplying a RF power of between about 500 watts and about 1000 watts for a 200 mm substrate. A gas distributor introduces the processing gas into the processing chamber between about 300 mils and about 450 mils from the substrate surface. The process described herein for oxygen-free silicon carbide layer deposition generally produces low k films having dielectric constants between about 3.5 and about 4.5.

Oxygen Doped Silicon Carbide Materials

Low dielectric constant (low K) materials may be deposited by reacting a processing gas including hydrogen gas and an oxygen-containing organosilicon compound to form a dielectric layer comprising carbon-silicon bonds and silicon-oxygen bonds and having a dielectric constant less than about 5. The low k material is referred to as an oxygen-doped silicon carbide layer and typically includes less than 15 atomic percent (atomic %) of oxygen or less, preferably having between about 3 atomic % and about 10 atomic % or less of oxygen. The oxygen-doped silicon carbide layer may be used as a barrier layer adjacent a conductive material or a hardmask dielectric layer in a metallization scheme for a damascene or dual damascene process. The oxygen-doped silicon carbide layer may also be used as an interlayer dielectric material, an etch stop, a chemical mechanical polishing resistant layer (CMP stop), or an anti-reflective coating (ARC). A thermal enhanced or plasma-enhanced chemical vapor deposition process may be used to deposit the low k dielectric material. The deposited low dielectric constant material may be treated following deposition by a hydrogen containing plasma.

Suitable organosilicon compounds include oxygen-containing aliphatic organosilicon compounds, oxygen-containing cyclic organosilicon compounds, or combinations thereof. Oxygen-containing aliphatic organosilicon compounds have linear or branched structures comprising one or more silicon atoms and one or more carbon atoms, and the structure includes silicon-oxygen bonds. Commercially available oxygen-containing aliphatic organosilicon compounds include alkylsiloxanes. Oxygen-containing cyclic organosilicon compounds typically have a ring comprising three or more silicon atoms and the ring may further comprise one or more oxygen atoms. Commercially available oxygen-containing cyclic organosilicon compounds include rings having alternating silicon and oxygen atoms with one or two alkyl groups bonded to each silicon atom. Preferred oxygen-containing organosilicon compounds are cyclic compounds.

Suitable oxygen-containing organosilicon compounds include, for example, one or more of the following compounds:

| | |
|---|---|
| Dimethyldimethoxysilane, | (CH₃)₂—Si—(OCH₃)₂, |
| 1,3-dimethyldisiloxane, | CH₃—SiH₂—O—SiH₂—CH₃, |
| 1,1,3,3-tetramethyldisiloxane | (CH₃)₂—SiH—O—SiH—(CH₃)₂, |
| (TMDSO), | |
| Hexamethyldisiloxane | (CH₃)₃—Si—O—Si—(CH₃)₃, |
| (HMDS), | |
| Hexamethoxydisiloxane | (CH₃O)₃—Si—O—Si—(OCH₃)₃, |
| (HMDSO), | |
| 1,3-bis(silanomethylene)disiloxne, | (SiH₃—CH₂—SiH₂)₂O, |
| Bis(1-methyldisiloxanyl)methane, | (CH₃—SiH₂—O—SiH₂)₂CH₂, |
| 2,2-bis(1-methyldisiloxanyl)propane, | (CH₃—SiH₂—O—SiH₂)₂C(CH₃) |
| 1,3,5,7-tetramethylcyclotetrasiloxane | ( SiHCH₃—O)₄ (cyclic), |
| (TMCTS), | |
| Octamethylcyclotetrasiloxane | ( Si(CH₃)₂—O)₄ (cyclic), |
| (OMCTS), | |
| 1,3,5,7,9-pentamethylcyclo- | ( SiHCH₃—O)₅ (cyclic), |
| pentasiloxane, | |
| 1,3,5,7-tetrasilano-2,6-dioxy- | ( SiH₂—CH₂—SiH₂—O)₂ |
| 4,8-dimethylene, | |
| Hexamethylcyclotrisiloxane | ( Si(CH₃)₂—O)₃ (cyclic), |

and fluorinated hydrocarbon derivatives thereof. The above lists are illustrative and should not be construed or interpreted as limiting the scope of the invention.

The processing gas for depositing the oxygen-doped silicon carbide layer may further include an oxygen-free organosilicon compound as described herein. When oxygen-containing and oxygen-free organosilicon precursors are used in the same processing gas, a molar ratio of oxygen-free organosilicon precursors to oxygen-containing organosilicon precursors between about 4:1 and about 1:1 is generally used.

The processing gas may also include hydrogen gas. The hydrogen gas is generally added at a molar ratio of oxygen-containing organosilicon compound to hydrogen gas of between about 1:1 and about 10:1, such as between about 1:1 and about 6:1. Preferred deposition processes for oxygen-containing organosilicon compounds and hydrogen gas has a molar ratio of oxygen-containing organosilicon compound to hydrogen gas of between about 1:1 and about 1.5:1.

The processing gas may further comprise an inert gas. Inert gases, such as a noble gas selected from the group of argon, helium, neon, xenon, or krypton, and combinations thereof, may be added to the processing gas to improve processing stability.

An oxygen-doped silicon carbide layer may be deposited in one embodiment by supplying oxygen-free and oxygen-containing organosilicon compounds, such as trimethylsilane and 1,3,5,7-tetramethylcyclotetrasiloxane, respectively, to a plasma processing chamber at a flow rate between about 10 milligrams/minute (mgm) and about 5000 mgm, respectively, supplying hydrogen gas at a flow rate between about 0 sccm and about 1000 sccm, optionally supplying a noble gas at a flow rate between about 1 sccm and about 10000 sccm, maintaining a substrate temperature between about 0° C. and about 500° C., maintaining a chamber pressure below about 500 Torr and a RF power of between about 0.03 watts/cm² and about 1500 watts/cm²m, such as between about 0.03 W/cm² and about 3.2 W/cm².

The RF power can be provided at a high frequency such as between 13 MHz and 14 MHz or a mixed frequency of the high frequency and the low frequency, for example, a high frequency of about 13.56 MHz and a low frequency of between about 100 KHz and about 1000 KHz, such as about 356 KHz. The RF power can be provided continuously or in short duration cycles wherein the power is on at the stated levels for cycles less than about 200 Hz and the on cycles total between about 10% and about 30% of the total duty cycle. A gas distributor may introduce the processing gas into the chamber, the gas distributor may be positioned between about 200 mils and about 700 mils from the substrate surface.

An oxygen-doped silicon carbide layer may be deposited in one embodiment by supplying an oxygen-containing organosilicon compound, such as 1,3,5,7-tetramethylcyclotetrasiloxane, and optionally, an oxygen-free organosilicon compound, such as trimethylsilane, to a plasma processing chamber at a flow rate between about 100 milligrams/minute (mgm) and about 5000 mgm, respectively, at a molar ratio of oxygen-free organosilicon compounds, i.e., trimethylsilane, to oxygen-containing organosilicon compounds, i.e., 1,3,5,7-tetramethylcyclotetrasiloxane, between about 4:1 and about 1:1, supplying hydrogen gas at a flow rate between about 10 sccm and about 200 sccm at a molar ratio of oxygen-containing organosilicon compounds, i.e., 1,3,5,7-tetramethylcyclotetrasiloxane, to hydrogen gas between about 6:1 and about 1:1, and at a molar ratio of oxygen-free organosilicon compound, i.e., trimethylsilane, to hydrogen gas between about 6:1 and about 1:1, supplying a noble gas at a flow rate between about 500 sccm and about 2000 sccm, maintaining a substrate temperature between about 250° C. and about 450° C., maintaining a chamber pressure between about 1 Torr and about 12 Torr and a RF power of between about 500 watts and about 1000 watts for a 200 mm substrate. The process described herein for oxygen-doped silicon carbide layer deposition generally produces low k films having dielectric constants between about 3.5 and about 4.5.

Silicon Oxycarbide Materials:

Low dielectric constant (low K) materials may be deposited by reacting a processing gas including hydrogen gas and an oxygen-containing organosilicon compound to form a dielectric layer comprising carbon, silicon, and oxygen, and having a dielectric constant less than about 3. The low k material is referred to as a silicon oxycarbide and typically includes greater than about 15 atomic percent (atomic %) of oxygen. The low k dielectric materials may be deposited by blending one or more oxygen-containing cyclic organosilicon compounds and one or more aliphatic compounds with hydrogen gas. The films contain a network of —Si—O—Si—ring structures that are cross-linked with one or more linear organic compounds. Because of the cross linkage, a reactively stable network is produced having a significant separation between ring structures and thus, the deposited films possess a significant degree of porosity. The deposition process can be either a thermal process or a plasma enhanced process. The silicon oxy carbide layer is preferably used as an interlayer dielectric material.

The oxygen-containing cyclic organosilicon compounds include a ring structure having three or more silicon atoms and the ring structure may further comprise one or more oxygen atoms. Commercially available cyclic organosilicon compounds include rings having alternating silicon and oxygen atoms with one or two alkyl groups bonded to the silicon atoms. For example, the oxygen containing cyclic organosilicon compounds may include one or more of the following compounds:

| | |
|---|---|
| 1,3,5,7-tetramethylcyclotetrasiloxane | ( SiHCH₃—O)₄ (cyclic), |
| (TMCTS), | |
| Octamethylcyclotetrasiloxane | ( Si(CH₃)₂—O)₄ (cyclic), |
| (OMCTS), | |
| 1,3,5,7,9-pentamethylcyclopentasiloxane, | ( SiHCH₃—O)₅ (cyclic), |
| 1,3,5,7-tetrasilano-2,6-dioxy- | ( SiH₂—CH₂—SiH₂—O)₂ |
| 4,8-dimethylene, | |
| Hexamethylcyclotrisiloxane | ( Si(CH₃)₂—O)₃ (cyclic), |

and fluorinated hydrocarbon derivatives thereof.

The aliphatic compounds include linear or branched (i.e. acyclic) organosilicon compounds having one or more silicon atoms and one or more carbon atoms, such as oxygen-free organosilicon compounds, and linear or branched hydrocarbon compounds having at least one unsaturated carbon bond. The structures may further comprise oxygen. Commercially available aliphatic organosilicon compounds include organosilanes that do not contain oxygen between silicon atoms and organosiloxanes that contain oxygen between two or more silicon atoms. Suitable oxygen-free organosilicon compounds are described above.

The aliphatic hydrocarbon compounds include compounds having between one and about 20 adjacent carbon atoms. The hydrocarbon compounds can include adjacent carbon atoms that are bonded by any combination of single, double, and triple bonds. For example, the organic compounds may include alkenes and alkynes having two to about 20 carbon atoms, such as ethylene, propylene, acetylene, and butadiene. Further examples of suitable hydrocarbons include t-butylethylene, 1,1,3,3-tetramethylbutylbenzene, t-butylether, metyl-methacrylate(MMA), t-butylfurfurylether, and combinations thereof.

The processing gas may also include hydrogen gas. The hydrogen gas is generally added at a molar ratio of oxygen-containing organosilicon compound to hydrogen gas of between about 1:1 and about 10:1, such as between about 1:1 and about 6:1. Preferred deposition processes for oxygen-containing organosilicon compounds and hydrogen gas has a molar ratio of oxygen-containing organosilicon compound to hydrogen gas of between about 1:1 and about 1.5:1.

The processing gas may further comprise an inert gas. Inert gases, such as a noble gas selected from the group of argon, helium, neon, xenon, or krypton, and combinations thereof, may be added to the processing gas to improve processing stability.

In an alternative embodiment of the deposition process for low k dielectric materials, the processing gas described herein may further include one or more meta-stable organic compounds. Meta-stable compounds are described herein as compounds having unstable functional groups that dissociate under applied processing conditions, such as by temperature applied during an annealing process. The meta-stable organic compounds form unstable components within the layer network. The unstable components may be removed from the deposited material using a post anneal treatment. The removal of the unstable component during the post anneal treatment forms a void within the network and reducing the lower dielectric constant of the deposited material. The meta-stable compound is also known as a “leaving group” because of the nature of the process whereby the meta-stable compound leaves the network to form one or more voids therein. For example, a t-butyl functional group dissociated from the molecule at about 200° C. to form ethylene (C₂H₄) by a beta hydrogenation mechanism and evolves from the substrate surface leaving behind a void in the deposited material.

The meta-stable organic compounds may include t-butylethylene, 1,1,3,3-tetramethylbutylbenzene, t-butylether, metyl-methacrylate (MMA), and t-butylfurfurylether. The meta-stable compounds may also be in the form of aliphatic compounds described herein. It is believed that the meta-stable organic compounds further reduce the dielectric constant of the deposited film. Preferably, t-butylether is used as the meta-stable organic precursor in the processing gases.

Preferably, the cyclic organosilicon compounds are combined with at least one aliphatic organosilicon compound and at least one aliphatic hydrocarbon compound. For example, the processing gas may include between about 5 percent by volume (vol %) and about 80 vol % of the one or more cyclic organosilicon compounds, between about 5 vol % and about 15 vol % of the one or more aliphatic organosilicon compounds, and between about 5 vol % and about 45 vol % of the one or more aliphatic hydrocarbon compounds. The processing gas also includes between 5 vol % and about 20 vol % of hydrogen gas. More preferably, the processing gas includes between about 45 vol % and about 60 vol % of one or more cyclic organosilicon compounds, between about 5 vol % and about 10 vol % of one or more aliphatic organosilicon compounds, and between about 5 vol % and about 35 vol % of one or more aliphatic hydrocarbon compounds.

A silicon oxycarbide layer may be deposited by introducing one or more cyclic organosilicon compounds at a flow rate between about 1,000 and about 10,000 mgm, preferably about 5,000 mgm, into a processing chamber, introducing one or more aliphatic organosilicon compounds at a flow rate between about 200 and about 2,000 mgm, preferably about 700 sccm, into the processing chamber, introducing one or more aliphatic hydrocarbon compounds at a flow rate between about 100 and about 10,000 sccm, preferably 1,000 sccm, introducing hydrogen gas at a flow rate between about 200 sccm and about 5,000 sccm, maintaining a temperature between about −20° C. and about 500° C., preferably between about 100° C. and about 450° C., maintaining a deposition pressure between about 1 Torr and about 20 Torr, preferably between about 4 Torr and about 7 Torr, and optionally, generating a plasma by applying a power density between about 0.03 W/cm² and about 3.2 W/cm², which corresponds to a RF power level of about 10 W to about 2000 W for a 200 mm substrate. The one or more meta-stable organic precursors may be added to the processing gases described herein in amounts between about 100 mgm and about 5000 mgm. The deposition rate for the silicon oxycarbide layer by the process described may be between about 10,000 Å/min and about 20,000 Å/min.

Preferably, the cyclic organosilicon compound is 1,3,5,7-tetramethylcyclotetrasiloxane, octamethylcyclotetrasiloxane, or a combination thereof, the aliphatic organosilicon compound is trimethylsilane, 1,1,3,3-tetramethyldisiloxane, or a combination thereof, and the aliphatic hydrocarbon compound is ethylene. Preferably, the meta-stable organic precursor is t-butylether if a meta-stable compound is used in the processing gas. The low k dielectric material comprises oxygen, silicon, and carbon, with an oxygen content between about 20 atomic % and about 40 atomic % based upon the total atoms of oxygen, silicon, and carbon.

In a plasma enhanced process for depositing the silicon oxycarbide materials, a controlled plasma is typically formed adjacent the substrate by RF energy applied to a gas distribution manifold. The RF power to the deposition chamber may be cycled or pulsed to reduce heating of the substrate and promote greater porosity in the deposited film. The RF power may be supplied by a single frequency RF power between about 0.01 MHz and 300 MHz or may be supplied using mixed, simultaneous frequencies to enhance the decomposition of the components of the processing gas. In one aspect, the mixed frequency is a lower frequency of about 12 kHz and a higher frequency of about 13.56 MHz. In another aspect, the lower frequency may range between about 300 Hz to about 1,000 kHz, and the higher frequency may range between about 5 MHz and about 50 MHz. Preferably, the RF power level is applied between about 300 W and about 1700 W when depositing the material by a plasma-enhanced chemical vapor deposition process.

The above process parameters for the deposition of silicon carbide, oxygen-doped silicon carbide, and silicon oxy-carbide provide a deposition rate for the low dielectric constant material in the range of about 500 Å/min to about 20,000 Å/min, when implemented on a 200 mm (millimeter) substrate in a deposition chamber available from Applied Materials, Inc., Santa Clara, Calif. The process described herein for silicon oxycarbide layer deposition generally produces low k films having dielectric constants between about 2.5 and about 3.5.

Further descriptions of depositing low k dielectric materials with met-stable compounds is disclosed in co-pending U.S. patent application Ser. No. ______, filed ______, entitled “Crosslink Cyclo-Siloxane Compound With Linear Bridging Group To Form Ultra Low K Dielectric,” (AMAT 6147) which is incorporated by reference herein to the extent not inconsistent with the claimed aspects and disclosure described herein.

Post Deposition Processing

Following deposition, the deposited low dielectric constant material may be annealed at a temperature between about 100° C. and about 400° C. for between about 1 minute and about 60 minutes, preferably at about 30 minutes, to reduce the moisture content and increase the solidity and hardness of the dielectric material. Annealing is preferably performed after the deposition of a subsequent material or layer that prevents shrinkage or deformation of the dielectric layer. The annealing process is typically formed using inert gases, such as argon and helium, but may also include hydrogen. The above described annealing process is preferably used for low dielectric constant materials deposited from processing gases without meta-stable compounds.

Alternatively, for materials deposited from processing gases containing meta-stable compounds, a post deposition anneal is used to remove unstable components from the layer as well as reduce the moisture content of the film. Moisture content may arise due to exposure to ambient air or by-product formation, for example. The anneal process is preferably performed prior to the subsequent deposition of additional materials. Preferably, an in-situ (i.e., inside the same chamber or same processing system without breaking vacuum) post treatment is performed.

The material containing unstable components is subjected to a temperature between about 100° C. and about 400° C. for between about 2 seconds and about 10 minutes, preferably about 30 seconds. The annealing gas includes helium, hydrogen, or a combination thereof, which is flowed into the chamber at a rate between about 200 sccm and about 10,000 sccm, such as between about 500 and about 1,500 sccm. The chamber pressure is maintained between about 2 Torr and about 10 Torr. A gas distribution head for providing the annealing gas to the process chamber is disposed between about 300 mils and about 600 mils from the substrate surface.

The annealing process is preferably performed in one or more cycles using helium. The annealing process may be performed more than once, and variable amounts of helium and hydrogen may be used in multiple processing steps or annealing steps. The post anneal may be performed in substitution or prior to the anneal step previously described herein. For example, a second in-situ anneal process may be performed on the materials deposited from processing gases containing meta-stable compounds following the initial anneal process to remove meta-stable components. The second anneal process that may be performed is the anneal process for deposited material that do not have meta-stable components as previously described herein. Alternatively, a RF power may be applied to the annealing gas between about 200 W and about 1,000 W, such as between about 200 W and about 800 W, at a frequency of about 13.56 MHz for a 200 mm substrate.

The deposited low dielectric constant material may be treated with a reducing plasma to remove contaminants or otherwise clean the exposed surface of the oxygen-doped silicon carbide layer prior to subsequent deposition of materials thereon. The plasma treatment may be performed in the same chamber used to deposit the silicon and carbon containing material.

The plasma treatment generally includes providing a reducing gas including hydrogen, ammonia, and combinations thereof, an inert gas including helium, argon, neon, xenon, krypton, or combinations thereof, to a processing chamber at a flow rate of between about 500 sccm and about 3000 sccm, preferably between about 1000 sccm and about 2500 sccm of hydrogen. The plasma is generated using a power density ranging between about 0.03 W/cm² and about 3.2 W/cm², which is a RF power level of between about 10 W and about 1000 W for a 200 mm substrate. Preferably, a power level of between about 200 watts and about 800 watts is used to generate the plasma. The RF power can be provided at a high frequency such as between 13 MHz and 14 MHz. The RF power can be provided continuously or in short duration cycles wherein the power is on at the stated levels for cycles less than about 200 Hz and the on cycles total between about 10% and about 30% of the total duty cycle.

The processing chamber is generally maintained at a chamber pressure of between about 3 Torr and about 12 Torr when generating the reducing plasma. A chamber pressure between about 5 Torr and about 10 Torr is preferably used. The substrate is maintained at a temperature between about 300° C. and about 450° C., preferably between about 350° C. and about 400° C. during the plasma treatment. The plasma treatment may be performed between about 10 seconds and about 100 seconds, with a plasma treatment between about 40 seconds and about 60 seconds preferably used. The processing gas may be introduced into the chamber by a gas distributor, the gas distributor may be positioned between about 200 mils and about 500 mils, preferably between about 300 mils and about 500 mils from the substrate surface. However, it should be noted that the respective parameters may be modified as necessary to treat the deposited materials described herein and to perform the plasma processes in various chambers and for different substrate sizes, such as 300 mm substrates.

The hydrogen containing plasma treatment is believed to further reduce the dielectric constant of the low k dielectric layer by about 0.1 or less. The plasma treatment is believed to clean contaminants from the exposed surface of the silicon carbide material and may be used to stabilize the layer, such that it becomes less reactive with moisture and/or oxygen under atmospheric condition as well as the adhesion of layers formed thereover.

The hydrogen containing plasma treatment is also believed to reduce the k value in silicon carbide and oxygen-doped silicon carbide material, and improve cracking resistance and layer hardness in silicon oxycarbide layers without detrimentally affecting the dielectric constant.

### DEPOSITION EXAMPLES

Silicon Carbide Layer:

A silicon carbide layer was deposited on a 200 mm substrate by supplying trimethylsilane to a processing chamber at a flow rate of about 150 sccm, supplying hydrogen gas at a flow rate of about 100 sccm, supplying helium at a flow rate of about 400 sccm, maintaining a substrate temperature of about 350° C., maintaining a chamber pressure of about 8.7 Torr, a spacing between the gas distributor and the substrate surface of about 515 mils, and a RF power of about 460 watts at a frequency of about 13.56 MHz. The process is performed for between about 70 seconds and about 80 seconds. The deposited silicon carbide material was observed to have a dielectric constant of about 4.24.

A silicon carbide layer deposited with the same process but without having hydrogen gas deposited silicon carbide material having a dielectric constant of about 4.35. Further silicon carbide deposition having hydrogen flow rates of 200 sccm, 400 sccm, and 600 sccm, produced silicon carbide material having dielectric constants of 4.32, 4.54, and 4.71, respectively.

Oxygen-doped Silicon Carbide Layer:

A low dielectric constant oxygen-doped silicon carbide layer was deposited on a 200 mm substrate by supplying 1,1,3,3-tetramethyidisiloxane (TMDSO) at a flow rate of about 2400 mgm and octamethylcyclotetrasiloxane (OMCTS) at a flow rate of about 2000 mgm, respectively, to a processing chamber, supplying hydrogen gas at a flow rate of about 400 sccm, supplying helium at a flow rate of about 400 sccm, maintaining a substrate temperature of about 350° C., maintaining a chamber pressure of about 6.75 Torr and supplying a RF power of between about 500 watts and about 1000 watts. The deposited layer was observed to have a dielectric constant of about 2.45. The deposition process was repeated using 480 sccm of oxygen in place of 400 sccm of hydrogen, and produced an oxygen doped silicon carbide layer having a dielectric constant of about 2.55. This hydrogen deposited oxygen-doped silicon carbide layer had improved or comparable low dielectric constants compared to oxygen deposited oxygen-doped silicon carbide layers.

Silicon Oxycarbide Layer:

A low k dielectric material was deposited on a 200 mm substrate by supplying octamethylcyclotetrasiloxane (OMCTS) at a flow rate of about 5,000 mgm, supplying trimethylsilane (TMS) at a flow rate of about 700 mgm, supplying ethylene at a flow rate of about 2,000 mgm, supplying hydrogen gas at a flow rate of about 400 sccm, supplying helium at a flow rate of about 1,000 sccm, maintaining a substrate temperature of about 400° C., maintaining a chamber pressure of about 6 Torr, and generating a plasma at a RF power of about 800 watts. The low k dielectric material had a dielectric constant of about 2.4 and a hardness of about 0.6 Gpa.

Following a hydrogen plasma treatment described herein, low k dielectric material had a dielectric constant of about 2.4 and a hardness of about 1.0 GPa. The post-deposition plasma treatment was also observed to improve interlayer adhesion of the low k dielectric material to adjacent materials. For example, silicon oxycarbide layer were also observed to have a wetting angle of greater than 90°, which indicates a hydrophobic layer with less than desirable interlayer adhesion properties, and wetting angles of less than 90°, such as 67°, which indicate improved interlayer adhesion, following the hydrogen plasma process.

The embodiments described herein for depositing low k dielectric materials are provided to illustrate the invention and the particular embodiment shown should not be used to limit the scope of the invention.

While the foregoing is directed to preferred embodiments of the present invention, other and further embodiments of the invention may be devised without departing from the basic scope thereof, and the scope thereof is determined by the claims that follow.

What is claimed is:

1. A method for depositing a low dielectric constant material, comprising:
introducing a processing gas comprising hydrogen gas and an oxygen-containing organosilicon compound, an oxygen-free organosilicon compound, or combinations thereof, to a substrate surface in a processing chamber; and
reacting the processing gas at processing conditions to deposit a low dielectric constant material on the substrate surface, wherein the low k dielectric material comprises at least silicon and carbon.

2. The method of claim 1, wherein the oxygen-containing organosilicon compound selected from the group of dimethyidimethoxysilane, 1,3-dimethyidisiloxane, 1,1,3,3-tetramethyidisiloxane (TMDSO), hexamethyidisiloxane (HMDS), 1,3-bis(silanomethylene)disiloxane, bis(1-methyldisiloxanyl)methane, 2,2-bis(1-methyldisiloxanyl)propane, hexamethoxydisiloxane (HMDOS), 1,3,5-trisilano-2,4,6-trimethylene, 1,3,5,7-tetramethylcyclotetrasiloxane (TMCTS), octamethylcyclotetrasiloxane (OMCTS), 1,3,5,7,9-pentamethylcyclopentasiloxane, 1,3,5,7-tetrasilano-2,6-dioxy-4,8-dimethylene, hexamethylcyclotrisiloxane, and combinations thereof.

3. The method of claim 1, wherein the oxygen-free organosilicon compound comprises an organosilane compound selected from the group of methylsilane, dimethylsilane, trimethylsilane, ethylsilane, disilanomethane, bis(methylsilano)methane, 1,2-disilanoethane, 1,2-bis(methylsilano)ethane, 2,2-disilanopropane, 1 ,3,5-trisilano-2,4,6-trimethylene, and combinations thereof.

4. The method of claim 1, wherein the dielectric material comprises silicon, oxygen, and carbon, and has an oxygen content of about 15 atomic % or less and has a dielectric constant between about 3.5 and about 4.5.

5. The method of claim 1, wherein the dielectric material comprises silicon, oxygen, and carbon, and has an oxygen content of greater than 15 atomic % oxygen and has a dielectric constant between about 2.5 and about 3.5.

6. The method of claim 1, wherein the processing gas further comprises an inert gas selected from the group of argon, helium, neon, xenon, or krypton, and combinations thereof.

7. The method of claim 1, wherein the processing gas further comprises hydrocarbon compounds, and combinations thereof.

8. The method of claim 7, wherein the hydrocarbon compounds are selected from the group consisting of ethylene, propylene, acetylene, butadiene, t-butylethylene, 1,1,3,3-tetramethylbutylbenzene, t-butylether, metyl-methacrylate (MMA), t-butylfurfurylether, and combinations thereof.

9. The method of claim 1, wherein the reacting of the processing gas comprises generating a plasma of the processing gas at a power density ranging from about 0.03 W/cm² to about 3.2 W/cm².

10. The method of claim 1, further comprising treating the low dielectric constant material on the substrate surface with a hydrogen containing plasma, an annealing process, or combinations thereof.

11. The method of claim 10, wherein the treating the low dielectric constant material comprises exposing the low dielectric constant material to a hydrogen containing plasma, comprising:
flowing a plasma gas of hydrogen, helium, or combinations thereof, at a rate between about 200 sccm and about 10,000 sccm across a surface of the layer for about 30 seconds; and
generating a plasma of the processing gas at a power density between about 0.03 W/cm² and about 3.2 W/cm².

12. The method of claim 10, wherein the treating the low dielectric constant material comprises annealing the substrate at a temperature between about 100° C. and about 400° C. for between about 1 minute and about 60 minutes.

13. The method of claim 1, wherein the processing gas further comprises a meta-stable compound.

14. The method of claim 13, wherein the meta-stable compound is selected from the group consisting of t-butylethylene, 1,1,3,3-tetramethylbutylbenzene, t-butylether, metyl-methacrylate (MMA), t-butylfurfurylether, and combinations thereof.

15. The method of claim 13, further comprising
converting the meta-stable organic compound to an unstable component in the low k dielectric material; and
annealing the deposited low dielectric constant material to remove the unstable component from the low k dielectric material.

16. The method of claim 15, wherein annealing the layer occurs at a temperature between about 100° C. and about 400° C. for between about 2 seconds and about 10 minutes.

17. A method for processing a substrate, comprising:
reacting a processing gas comprising:
one or more cyclic organosilicon compounds;
one or more aliphatic compounds; and
hydrogen gas; and
delivering the processing gas to a substrate surface at conditions sufficient to deposit a low dielectric constant layer on a substrate surface.

18. The method of claim 17, wherein the one or more cyclic organosilicon compounds is selected from the group of 3,5-trisilano-2,4,6-trimethylene, 1,3,5,7-tetramethylcyclotetrasiloxane (TMCTS), octamethylcyclotetrasiloxane (OMCTS), 1,3,5,7,9-pentamethylcyclopentasiloxane, 1,3,5,7-tetrasilano-2,6-dioxy-4,8-dimethylene, and hexamethylcyclotrisiloxane.

19. The method of claim 17, wherein the one or more aliphatic compounds comprise aliphatic organosilicon compounds, hydrocarbon compounds, or a mixture thereof.

20. The method of claim 19, wherein the aliphatic organosilicon compounds are selected from the group consisting of methylsilane, dimethylsilane, trimethylsilane, dimethyldimethoxysilane, ethylsilane, disilanomethane, bis(methylsilano)methane, 1,2-disilanoethane, 1,2-bis(methylsilano)ethane, 2,2-disilanopropane, 1,3-dimethyidisiloxane, 1,1,3,3-tetramethyldisiloxane (TMDSO), hexamethyldisiloxane (HMDS), 1,3-bis(silanomethylene)disiloxane, bis(1-methyldisiloxanyl)methane, 2,2-bis(1-methyldisiloxanyl)propane, diethylsilane, propylsilane, vinylmethylsilane, 1,1,2,2-tetramethyidisilane, hexamethyldisilane, 1,1,2,2,3,3-hexamethyltrisilane, 1,1,2,3,3-pentamethyltrisilane, dimethyldisilanoethane, dimethyldisilanopropane, tetramethyldisilanoethane, and tetramethyidisilanopropane.

21. The method of claim 19, wherein the hydrocarbon compounds are selected from the group consisting of ethylene, propylene, acetylene, ethylene, propylene, acetylene, butadiene, t-butylethylene, 1,1,3,3-tetramethylbutylbenzene, t-butylether, metyl-methacrylate (MMA), and t-butylfurfurylether.

22. The method of claim 17, wherein the conditions comprise generating a plasma at a power density between about 0.03 W/cm² and about 3.2 W/cm², maintaining a substrate temperature of about 100° C. to about 400° C., and maintaining a chamber pressure between about 1 Torr and about 12 Torr.

23. The method of claim 17, wherein the gas mixture comprises:
about 5 percent by volume to about 80 percent by volume of the one or more cyclic organosilicon compounds;
about 5 percent by volume to about 15 percent by volume of one or more aliphatic organosilicon compounds;
about 5 percent by volume to about 45 percent by volume of one or more aliphatic hydrocarbon compounds; and
about 5 percent by volume to about 20 percent by volume of the hydrogen gas.

24. The method of claim 17, further comprising treating the deposited layer with a plasma of helium, hydrogen, or a mixture thereof at conditions sufficient to increase the hardness of the film.

25. The method of claim 17, wherein the processing gas further comprises a meta-stable compound.

26. The method of claim 25, wherein the meta-stable compound is selected from the group consisting of t-butylethylene, 1,1,3,3-tetramethylbutylbenzene, t-butylether, metyl-methacrylate (MMA), t-butylfurfurylether, and combinations thereof.

27. The method of claim 25, further comprising:
converting the meta-stable organic compound to an unstable component in the low k dielectric material; and
annealing the deposited low dielectric constant material to remove the unstable component from the low k dielectric material.

28. The method of claim 27, wherein annealing the layer occurs at a temperature between about 100° C. and about 400° C. for between about 2 seconds and about 10 minutes.

29. The method of claim 17, wherein the processing gas further comprises an inert gas selected from the group of argon, helium, neon, xenon, or krypton, and combinations thereof.
